(19) United States
(12) Patent Application Publication
(10) Pub. No.: US 2010/0127401 A1
(43) Pub. Date: May 27, 2010

(54) SEMICONDUCTOR DEVICE

(76) Inventor: Dae Kyeun Kim, Gyeonggi-do (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/625,159

(22) Filed: Nov. 24, 2009

(30) Foreign Application Priority Data
Nov. 27, 2008 (KR) 10-2008-0118861

(51) Int. Cl. H01L 23/48

(52) U.S. Cl. 257/773; 257/E23.01

(57) ABSTRACT

Disclosed is a semiconductor device. The semiconductor device includes a circuit part, a pad metal aligned over the circuit part to electrically connect the circuit part, and a metal layer interposed between the pad metal and the circuit part to electrically connect the pad metal to the circuit part. A buffer layer including an insulating layer with metal patterns having a slit shape formed therein is formed within the metal layer.

### CROSS-REFERENCE TO RELATED APPLICATION

This application claims the benefit under 35 U.S.C. §119 of Korean Patent Application No. 10-2008-0118861, filed Nov. 27, 2008, which is hereby incorporated by reference in its entirety.

### BACKGROUND

A semiconductor device typically includes internal circuits having various functions. The internal circuits must be electrically connected to an external system to perform their own functions. In order to electrically connect the internal circuits of the semiconductor device to the external system, the semiconductor device includes pads.

Conductive lines including gold (Au) are bonded to the pads through bonding wires, so that the internal circuits can make data communication with the external system. At this time, a metal thin film, such as an aluminum thin film, is formed on a bonding part of the semiconductor device to facilitate the bonding process. The bonding part is called a pad. In general, the pad has a rectangular structure.

### BRIEF SUMMARY

Embodiments of the present invention provide a semiconductor device having a pad capable of electrically connecting internal circuits to an external system.

A semiconductor device according to an embodiment includes a circuit part; a pad metal aligned over the circuit part to electrically connect with the circuit part; a metal layer interposed between the pad metal and the circuit part to electrically connect the pad metal to the circuit part; and, a buffer layer formed in a region of the metal layer, wherein the buffer layer includes an insulating layer and metal patterns having slit shapes.

### BRIEF DESCRIPTION OF THE DRAWINGS

FIG. 1 is a view showing a structure of a semiconductor device according to an embodiment;

FIG. 2 is a plan view of a top metal layer according to an embodiment;

FIG. 3 is a plan view of a first buffer layer according to an embodiment;

FIG. 4 is a view showing a plurality of patterns defined by metal patterns according to an embodiment;

FIG. 5 is a plan view of a second buffer layer according to an embodiment; and

FIG. 6 is a view showing a first buffer layer in comparison with a second buffer layer.

### DETAILED DESCRIPTION

Hereinafter, embodiments will be described in detail with reference to accompanying drawings.

In the following description, the term “include(s)” does not exclude other components or steps. In addition, layers and regions may be magnified in the drawings to clearly express the layers and regions. For convenience, the same reference numerals will be used to refer to the same elements throughout the specification and drawings. When a layer, a film, a region, or a plate is referred to as being “on” another layer, film, region or plate, it can be directly on another layer, film, region or plate, or intervening layers may also be present.

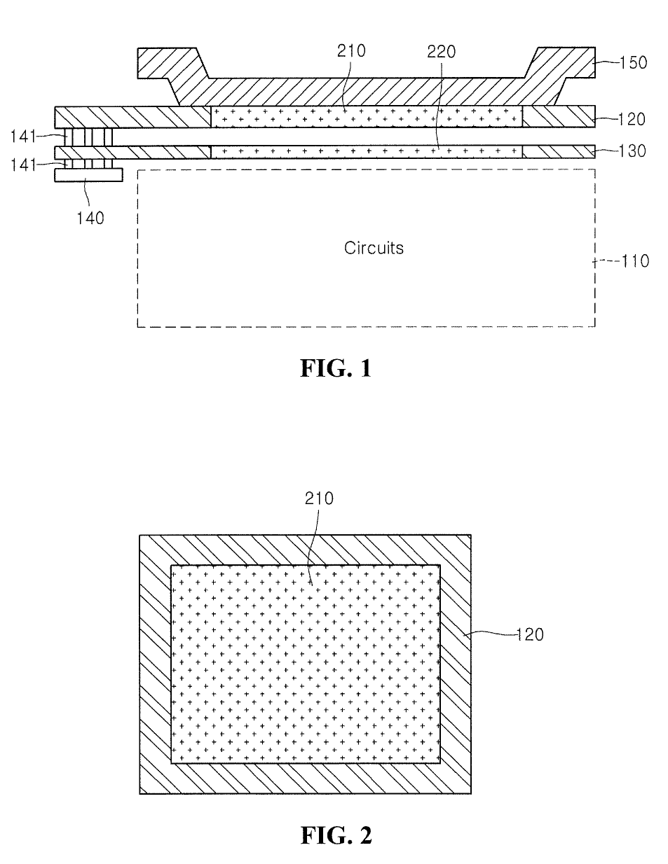

FIG. 1 is a view showing a structure of a semiconductor device according to an embodiment, and FIG. 2 is a plan view of a top metal layer according to an embodiment.

Referring to FIG. 1, the semiconductor device in accordance with an embodiment has a CUP (Circuit Under Pad) structure in which a metal pad 150 is formed on a circuit part 110. A single metal layer or two or more metal layers can be formed below the metal pad 150.

The number of metal layers can be further added according to embodiments. According to one embodiment, the metal layer includes a top metal layer 120 partially making contact with the metal pad 150, and a bottom metal layer 130 interposed between the top metal layer 120 and the circuit part 110.

In addition, an extension metal pattern 140 can be formed at one side of the top metal layer 120 or the bottom metal layer 130 for the purpose of electric connection with the circuit part 110. If only the top metal layer 120 is formed between the metal pad 150 and the circuit part 110, the extension metal pattern 140 is formed at one side of the top metal layer 120. An insulating layer can be interposed between the top metal layer 120 and the bottom metal layer 130 for the purpose of insulation. A via plug 141 is formed through the insulating layer to make electric connection among the top metal layer 120, the bottom metal layer 130, and the extension metal pattern 140.

In addition, first and second buffer layers 210 and 220 are formed in the top metal layer 120 and the bottom metal layer 130, respectively, in order to inhibit external impact or stress from being transferred to the circuit part 110. The first and second buffer layers 210 and 220 are formed with a plurality of slits.

As shown in FIG. 1, if the top metal layer 120 and the bottom metal layer 130 are formed below the metal pad 150, the shape of the slits of the second buffer layer 220 formed in the bottom metal layer 130 may be configured by taking the shape of the slits formed in the first buffer layer 210 into consideration.

For instance, the alignment direction of the slits formed in the first buffer layer 210 may be perpendicular to the alignment direction of the slits formed in the second buffer layer 220 such that damping effect can be achieved by the first and second buffer layers 210 and 220.

Since the damping effect can be generated by the first and second buffer layers 210 and 220 respectively formed in the top and bottom metal layers 120 and 130, external impact applied to the metal pad 150 may not be transferred to the circuit part 110. The buffer layers will be described later in detail with reference to the accompanying drawings.

Meanwhile, the top metal layer 120 making contact with the metal pad 150 has an opening for receiving the first buffer layer 210, so that only a part of the top metal layer 120 around the opening directly makes contact with the metal pad 150.

Referring to FIG. 2, the top metal layer 120 surrounds the first buffer layer 210, and a contact surface between the top metal layer 120 and the metal pad 150 can be significantly reduced as compared with that of the related art.

That is, the contact surface between the top metal layer 120 and the metal pad 150 may have a circular shape or a rectangular shape in the form of a strip. If the first buffer layer 210 is patterned or manufactured simultaneously with the metal layer 120, the top metal layer 120 may include a metal contact part making contact with the metal pad 150, and a receiving part for receiving the first buffer layer 210 in the metal contact part.

The first buffer layer 210 is surrounded by the top metal layer 120, so that the first buffer layer 210 is defined by the opening of the top metal layer 120.

Hereinafter, description will be made with respect to the first buffer layer 210 formed at a part of an inner portion of the top metal layer and the second buffer layer 220 formed at a part of an inner portion of the bottom metal layer 130.

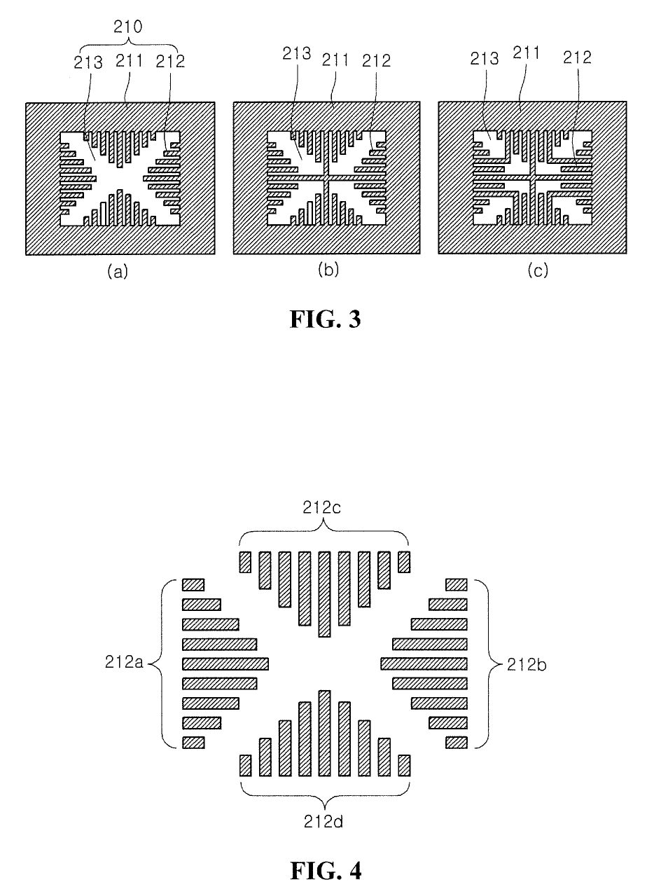

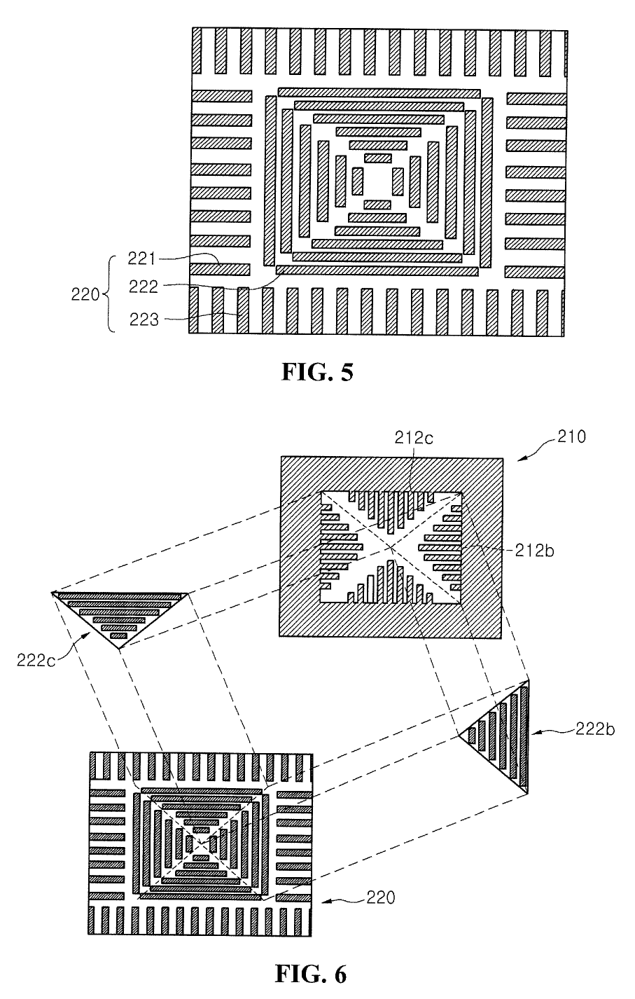

FIG. 3 is a plan view of the first buffer layer according to certain embodiments, FIG. 4 is a view showing a plurality of patterns defined by metal patterns according to an embodiment, FIG. 5 is a plan view of the second buffer layer according to an embodiment, and FIG. 6 is a view showing the first buffer layer in comparison with the second buffer layer.

In the following description, the buffer layer shown in FIG. 3 will be referred to as the first buffer layer formed in the top metal layer, and the buffer layer shown in FIG. 5 will be referred to as the second buffer layer formed in the bottom metal layer. However, the position of the first and second buffer layers can be interchanged, and one of the first and second buffer layers may be formed as an empty space.

It should be noted that the shapes of the buffer layers are not limited to the shapes shown in the drawings.

The external impact or stress can be buffered by the insulating layer constituting the buffer layers as well as the metal pattern formed in the insulating layer. In addition, when manufacturing the semiconductor device according to one embodiment, the buffer layers having the patterns shown in FIGS. 3 and 5 are formed in the metal layer. Otherwise, for another embodiment, in a state in which the buffer layers have been previously manufactured, the metal layers 120 and 130 are manufactured and then the buffer layers are inserted into the opening of the metal layers 120 and 130.

FIGS. 3 (a), (b), and (c) show example shapes of the first buffer layer when viewed in a plan view. The following description about the first buffer layer will be made on the basis of the plan views.

The first buffer layer 210 includes an insulating layer 213 and metal patterns 211 and 212 formed in the insulating layer 213. The insulating layer 213 can include a fluorosilicate glass (FSG)-based oxide layer or low-K material. The metal patterns 211 and 212 include aluminum or copper. The layout of the metal layers can be modified such that the buffer layers can be formed when the metal layers 120 and 130 are manufactured.

In the case of the first buffer layer shown in (a) of FIG. 3, the first buffer layer includes the insulating layer 213 and the metal line 211 disposed at an outer peripheral portion or an outer portion of the insulating layer 213 while surrounding the insulating layer 213. A plurality of metal patterns 212 having a slit shape are aligned in the insulating layer 213.

That is, when viewed in the plan view, the first buffer layer includes the metal line 211 forming the outer peripheral part or the outer peripheral surface of the first buffer layer, the insulating layer 213 formed in an area defined by the metal line 211, and the metal patterns 212 aligned in the insulating layer 213 in the form of slits.

The metal patterns 212 can have linear shapes and one end of each metal pattern 212 is connected to the metal line 211. In addition, the first buffer layer can be divided into several areas by the alignment of the metal patterns 212. That is, a plurality of structural patterns can be formed by the metal patterns 212.

The structural patterns formed by the metal patterns 212 will be explained with reference to FIG. 4.

FIG. 4 shows the structural patterns defined by the metal patterns of the first buffer layer illustrated in FIG. 3.

A plurality of structural patterns is formed in the insulating layer 213 by the metal patterns having the slit shape. In order to form the structural patterns, a via hole or a trench is formed by etching the insulating layer 213 and metal such as aluminum or copper is deposited in the via hole or the trench, and then the deposited metal is planarized.

In addition, when viewed in the plan view, the structural patterns formed by the metal patterns 212 include first structural patterns 212a, second structural patterns 212b opposite to the first structural patterns 212a, third structural patterns 212c aligned between the first and second structural patterns 212a and 212b, and fourth structural patterns 212d opposite to the third structural patterns 212c.

Each of the first to fourth structural patterns 212a to 212d may have at least one metal pattern. The first to fourth structural patterns 212a to 212d may have the same shape with different directionality.

That is, the first to fourth structural patterns 212a to 212d having the same shape and number are aligned in the insulating layer 213 while extending in directions different from each other. Such an alignment of the first to fourth structural patterns 212a to 212d is shown in (a) of FIG. 3. In addition, (b) and (c) of FIG. 3 illustrate the first buffer layer when specific metal patterns of the first to fourth structural patterns 212a to 212d are connected to each other.

In addition, the first structural patterns 212a can be formed by a plurality of the metal patterns 212, and the second structural patterns 212b can be formed while being spaced apart from the first structural patterns 212a. At this time, the plurality of metal patterns 212 constituting the second structural patterns 212b is symmetrical to the metal patterns 212 constituting the first structural patterns 212a.

Further, the metal patterns 212 constituting the third structural patterns 212c may be symmetrical to the metal patterns 212 constituting the fourth structural patterns 212d.

In addition, one metal pattern 212 of the first structural patterns 212a can be connected to one metal pattern of the second structural patterns 212b, and a specific metal pattern of the third structural patterns 212c can be connected to a specific metal pattern of the fourth structural patterns 212d. The buffer layer having this configuration is shown in (b) of FIG. 3.

In addition, one metal pattern 212 of the first structural patterns 212a can be connected to specific patterns of the second, third, and fourth structural patterns 212b, 212c, and 212d, another metal pattern of the second structural patterns 212b can be connected to specific patterns of the third and fourth structural patterns 212c and 212d, and yet another metal pattern 212 of the third structural patterns 212c can be connected to a specific pattern of the fourth structural patterns 212d. The buffer layer having this configuration is shown in (c) of FIG. 3.

The alignment of the metal patterns may not be limited to the above configuration, but can be variously realized according to embodiments.

Hereinafter, the shape of the second buffer layer aligned below the first buffer layer having the above-mentioned structural patterns will be described with reference to FIG. 5.

As mentioned above, the first and second buffer layers are formed in the top and bottom metal layers 120 and 130, respectively. In addition, the alignment and shape of the metal patterns of the second buffer layer formed in the bottom metal layer 130 are determined by taking the alignment and shape of the metal pattern of the first buffer layer into consideration.

That is, in order to further attenuate the external impact or stress by using the first and second buffer layers having the metal patterns, the alignment of the metal patterns of one buffer layer is determined by taking the alignment of the metal patterns of the other buffer layer adjacent to one buffer layer.

Referring to FIG. 5, the second buffer layer 220 of one embodiment includes an insulating layer 223, such as an oxide layer, and a plurality of metal patterns 221 and 222 formed in the insulating layer 223. The metal patterns 221 and 222 constituting the second buffer layer 220 may be aligned perpendicularly to the metal line 211 or the metal patterns 212 of the first buffer layer 210.

In more detail, when viewed in the plan view, the first metal patterns 221 are aligned in an area corresponding to the metal lines 211 of the first buffer layer 210, and the second metal patterns 222 of the second buffer layer 220 are aligned perpendicularly to the metal patterns 212 of the first buffer layer 210.

That is, the first metal patterns 221 of the second buffer layer 220 are aligned along the outer peripheral portion or an outer surface of the second buffer layer 220 while being spaced apart from each other. In addition, the first metal patterns 221 are positioned below the metal lines 211 of the first buffer layer 210 while being perpendicular to the metal lines 211 of the first buffer layer 210.

In other words, the first metal patterns 221 of the second buffer layer 220 are aligned in a predetermined area of the insulating layer 230 corresponding to the metal lines 211 of the first buffer layer 210 while being spaced apart from each other.

In addition, the second metal patterns 222 of the second buffer layer 220 are aligned in a predetermined area of the insulating layer 230 corresponding to the metal patterns 212 of the first buffer layer 210. Especially, some of the second metal patterns 222 having the slit shape may be perpendicular to the metal patterns 212 of the first buffer layer.

Therefore, due to the alignment of the second metal patterns 222 of the second buffer layer 220, the second buffer layer 220 is also divided into a plurality of structural patterns including the second metal patterns 222. FIG. 5 shows the second metal patterns 222 which can be aligned perpendicularly to the metal patterns 212 shown in FIG. 3.

As a result, since some of the second metal patterns 222 formed in the second buffer layer are perpendicular to the metal patterns 212 of the first buffer layer, the external impact or stress applied to the metal layer can be attenuated or reduced by the first and second buffer layers having the structural metal patterns.

FIG. 6 shows the first and second buffer layers 210 and 220 having structural patterns corresponding to each other.

As described above, the first buffer layer 210 is formed with first to fourth structural patterns defined by the metal patterns 212 having the slit shape. The following description will be made while focusing on the third and fourth structural patterns 212c and 212d.

Similar to the first buffer layer 210 formed with the structural patterns, the second buffer layer 220 has structural patterns defined by the metal patterns having the slit shape.

For instance, if the metal patterns constituting the third structural pattern 212c formed in the first buffer layer 210 are longitudinally aligned, the metal patterns are latitudinally formed in a predetermined area of the second buffer layer corresponding to the third structural pattern 212c.

That is, the metal patterns 222 in the predetermined area of the second buffer layer 220 corresponding to the third structural patterns 212c of the first buffer layer 210 can be referred to as fifth structural patterns 222c, and the metal patterns 222 constituting the fifth structural patterns 222c are aligned perpendicularly to the metal patterns 212 of the third structural patterns 212c.

In addition, if the metal patterns constituting the fourth structural patterns 212b of the first buffer layer 210 are latitudinally aligned, the metal patterns of sixth structural patterns 222b of the second buffer layer 220, which correspond to the fourth structural patterns 212b of the first buffer layer 210, are longitudinally aligned such that the sixth structural patterns 222b can be perpendicular to the fourth structural patterns 212b. Therefore, the metal patterns aligned in the specific area of the first buffer layer 210 can be aligned perpendicularly to the metal patterns formed in the corresponding area of the second buffer layer 220.

However, it is not necessary to align all metal patterns of the second buffer layer 220 perpendicularly to the metal patterns of the first buffer layer 210. The alignment of the metal patterns can be properly adjusted to attenuate external impact.

As mentioned above, according to the semiconductor device of the embodiment, the circuit part is formed below the metal pad, so that the chip area can be reduced and external impact and stress applied to the pad can be inhibited from being transferred to the circuit part.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a circuit part;
a pad metal aligned over the circuit part to electrically connect to the circuit part;
a metal layer interposed between the pad metal and the circuit part to electrically connect the pad metal to the circuit part; and
a buffer layer comprising an insulating layer and metal patterns having slit shapes formed in the insulating layer, wherein the buffer layer is disposed in the metal layer.

2. The semiconductor device of claim 1, wherein the metal patterns having the slit shapes are aligned within the insulating layer while being spaced apart from each other at a predetermined interval when viewed in a plan view.

3. The semiconductor device of claim 1, wherein the metal layer has a portion making contact with a bottom surface of the pad metal, and a space for receiving the buffer layer.

4. The semiconductor device of claim 1, wherein the metal layer includes a top metal layer partially making contact with the pad metal, and a bottom metal layer interposed between the top metal layer and the circuit part, the buffer layer comprising a first buffer layer formed in the top metal layer and a second buffer layer formed in the bottom metal layer.

5. The semiconductor device of claim 1, wherein the buffer layer further comprises metal lines formed at an outer peripheral portion of the buffer layer, wherein the insulating layer is disposed within a region defined by the metal lines.

6. A semiconductor device comprising:
a pad metal for electrically connecting a circuit part aligned below the pad metal to an external system;
a first metal layer for electrically connecting the circuit part to the pad metal;
a first buffer layer buried in the first metal layer;
a second metal layer for electrically connecting the circuit part to the first metal layer; and
a second buffer layer buried in the second metal layer,
wherein the first and second buffer layers each comprise insulating layers and metal patterns having slit shapes.

7. The semiconductor device of claim 6, wherein, when viewed in a plan view, the first buffer layer has at least one structural pattern defined by the metal patterns of the first buffer layer, and
wherein the at least one structural pattern of the first buffer layer comprises a first structural pattern comprising a first plurality of the metal patterns of the first buffer layer, the metal patterns of the first plurality being aligned in a first alignment direction.

8. The semiconductor device of claim 7, wherein the at least one structural pattern of the first buffer layer further comprises a second structural pattern comprising a second plurality of the metal patterns of the first buffer layer, the metal patterns of the second plurality being aligned in a second alignment direction.

9. The semiconductor device of claim 7, wherein, when viewed in a plan view, the second buffer layer has at least one structural pattern defined by the metal patterns of the second buffer layer, and
wherein a third structural pattern of the at least one structural pattern of the second buffer layer is aligned perpendicularly to the first alignment direction of the metal patterns of the first structural pattern of the first buffer layer, wherein the third structural pattern is disposed in a region corresponding to the first structural pattern.

10. The semiconductor device of claim 6, wherein the first buffer layer further comprises metal lines formed at an outer peripheral portion of the first buffer layer, and
wherein a plurality of the metal patterns of the second buffer layer having the slit shape are aligned in a predetermined area of the second buffer layer corresponding to the metal lines of the first buffer layer, while being spaced apart from each other at a predetermined interval.

11. The semiconductor device of claim 6, further comprising an extension metal pattern formed at one side of the first metal layer or the second metal layer to make electric connection with the circuit part.

12. The semiconductor device of claim 6, wherein the first metal layer comprises a contact part partially making contact with the pad metal, and a receiving part for receiving the first buffer layer.
